(19) United States
(12) Patent Application Publication
(10) Pub. No.: US 2017/0373175 A1
(43) Pub. Date: Dec. 28, 2017

(54) SYSTEMS AND METHODS FOR PROVIDING VERTICAL ACCESS TO THE COLLECTOR OF A HETEROJUNCTION BIPOLAR TRANSISTOR

(71) Applicant: QUALCOMM Incorporated, San Diego, CA (US)

(72) Inventors: Shiqun GU, San Diego, CA (US); Gengming TAI, San Diego, CA (US); Je-Hsiung LAN, San Diego, CA (US); Matthew Michael NOWAK, San Diego, CA (US); Miguel MIRANDA CORBALAN, San Diego, CA (US); Steve FANELLI, San Marcos, CA (US)

(21) Appl. No.: 15/192,773

(22) Filed: Jun. 24, 2016

(51) Int. Cl. H01L 29/737; H01L 23/31; H01L 29/08; H01L 29/66

(52) U.S. Cl. CPC H01L 29/7371; H01L 29/66242; H01L 23/3171; H01L 29/0817; H01L 29/0821

(57) ABSTRACT

Disclosed is a heterojunction bipolar transistor, and method of manufacturing the same, including an emitter having a conductive emitter contact coupled to a first side of the emitter, a first side of a base coupled to a second side of the emitter opposite the first side of the emitter, a collector coupled to the base on a second side of the base opposite the emitter, wherein an area of a junction between the base and the collector is less than or equal to an area of a junction between the base and the emitter, a first conductive base contact coupled to the base, and a conductive collector contact coupled to the collector on the side of the collector opposite the emitter and substantially parallel to the first conductive base contact.

### INTRODUCTION

Aspects relate to systems and methods for providing vertical access to the collector of a heterojunction bipolar transistor (HBT).

A bipolar transistor (also referred to as a bipolar junction transistor (BJT)) is a type of transistor that uses both electron and hole charge carriers. Bipolar transistors are available as individual components or fabricated in integrated circuits. The basic function of a bipolar transistor is to amplify current, which allows them to be used as amplifiers or switches, giving them wide applicability in electronic equipment, such as computers, televisions, cellular phones, audio amplifiers, and radio transmitters.

An HBT is a type of bipolar transistor that uses different semiconductor materials for the emitter and base regions, thereby creating a heterojunction. An HBT may utilize III-V compound semiconductor materials, which have high carrier mobilities and direct energy gaps, making them useful for optoelectronics. An HBT improves on a BJT in that it can handle signals of very high frequencies, for example, up to several hundred GHz. HBTs are commonly used in modern ultrafast circuits, such as RF systems, and in applications requiring a high power efficiency, such as RF power amplifiers in cellular phones.

### SUMMARY

The following presents a simplified summary relating to one or more aspects disclosed herein. As such, the following summary should not be considered an extensive overview relating to all contemplated aspects, nor should the following summary be regarded to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a heterojunction bipolar transistor includes an emitter having a conductive emitter contact coupled to a first side of the emitter, a first side of a base coupled to a second side of the emitter opposite the first side of the emitter, a collector coupled to the base on a second side of the base opposite the emitter, wherein an area of a junction between the base and the collector is less than or equal to an area of a junction between the base and the emitter, a first conductive base contact coupled to the base, and a conductive collector contact coupled to the collector on the side of the collector opposite the emitter and substantially parallel to the first conductive base contact.

In an aspect, a method of manufacturing a heterojunction bipolar transistor includes forming an emitter having a conductive emitter contact coupled to a first side of the emitter, forming a base having a first side coupled to a second side of the emitter opposite the first side of the emitter, forming a collector coupled to the base on a second side of the base opposite the emitter, wherein an area of a junction between the base and the collector is less than or equal to an area of a junction between the base and the emitter, forming a first conductive base contact coupled to the base; and forming a conductive collector contact coupled to the collector on the side of the collector opposite the emitter and substantially parallel to the first conductive base contact.

In an aspect, a heterojunction bipolar transistor includes means for emitting having a conductive emitter contact coupled to a first side of the means for emitting, a first side of a means for providing a base coupled to a second side of the means for emitting opposite the first side of the means for emitting, means for collecting coupled to the means for providing the base on a second side of the means for providing the base opposite the means for emitting, wherein an area of a junction between the means for providing the base and the means for collecting is less than or equal to an area of a junction between the means for providing the base and the means for emitting, a first conductive base contact coupled to the means for providing the base, and a conductive collector contact coupled to the means for collecting on the side of the means for collecting opposite the means for emitting and substantially parallel to the first conductive base contact.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure will be readily obtained as the same becomes better understood by reference to the following detailed description when considered in connection with the accompanying drawings which are presented solely for illustration and not limitation of the disclosure, and in which:

FIG. 1 is a simplified diagram of an exemplary conventional heterojunction bipolar transistor (HBT) that may be incorporated into a semiconductor device.

FIG. 2 is a simplified diagram of an exemplary HBT according to at least one aspect of the disclosure.

FIGS. 3A-3G illustrate a series of exemplary operations for fabricating an exemplary HBT according to at least one aspect of the disclosure.

FIGS. 4A-4B are several graphs illustrating the improved performance of the HBT of the present disclosure over a conventional HBT.

FIG. 5 illustrates an exemplary flow for manufacturing an HBT according to at least one aspect of the disclosure

### DETAILED DESCRIPTION

Disclosed is a heterojunction bipolar transistor. In an aspect, the heterojunction bipolar transistor includes an emitter having a conductive emitter contact coupled to a first side of the emitter, a first side of a base coupled to a second side of the emitter opposite the first side of the emitter, a collector coupled to the base on a second side of the base opposite the emitter, wherein an area of a junction between the base and the collector is less than or equal to an area of a junction between the base and the emitter, a first conductive base contact coupled to the base, and a conductive collector contact coupled to the collector on the side of the collector opposite the emitter and substantially parallel to the first conductive base contact.

Also disclosed is a method of manufacturing a heterojunction bipolar transistor. In an aspect, the method includes forming an emitter having a conductive emitter contact coupled to a first side of the emitter, forming a base having a first side coupled to a second side of the emitter opposite the first side of the emitter, forming a collector coupled to the base on a second side of the base opposite the emitter, wherein an area of a junction between the base and the collector is less than or equal to an area of a junction between the base and the emitter, forming a first conductive base contact coupled to the base; and forming a conductive collector contact coupled to the collector on the side of the collector opposite the emitter and substantially parallel to the first conductive base contact.

These and other aspects of the disclosure are disclosed in the following description and related drawings directed to specific aspects of the disclosure. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

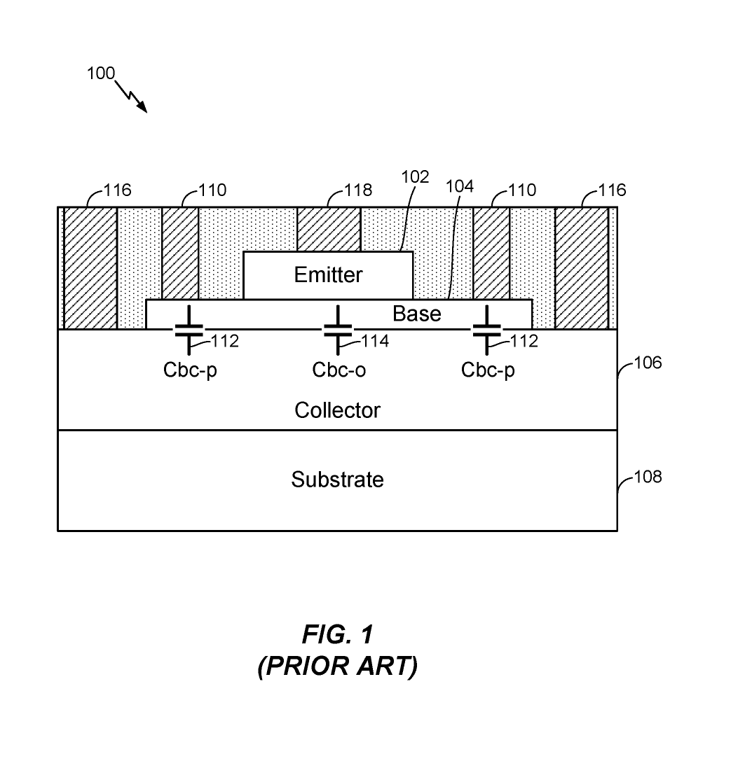

FIG. 1 is a simplified diagram of an exemplary conventional heterojunction bipolar transistor (HBT) 100 that may be incorporated into a semiconductor device. The HBT 100 includes an emitter 102, a base 104, a collector 106, a substrate 108, two base contacts 110, two collector contacts 116, and an emitter contact 118. Note that although FIG. 1 illustrates two base contacts 110 and two collector contacts 116, there may be more or fewer than two base contacts 110 and/or collector contacts 116. The HBT 100 uses different semiconductor materials for the junction between the emitter 102 and the base 104 and the junction between the base 104 and the collector 106, thereby resulting in “heterojunctions.” Further, the HBT 100 may utilize, for example, III-V semiconductor materials. The substrate 108 may be a III-V substrate, and may be, for example, silicon, gallium arsenide (GaAs), or indium phosphide.

For high frequency operation, a lower base-to-collector capacitance (“Cbc”), or base-collector capacitance, is desirable. The Cbc can be divided into two parts, the Cbc of the junction between the base 104 and the collector 106 of the area of the collector 106 underneath the emitter 102, referred to as Cbc-o 114, and the Cbc of the junction between the base 104 and the collector 106 outside of the area of the emitter 102, referred to as Cbc-p 112. The Cbc-o 114 underneath the emitter 102 enables direct carrier injection (where the carrier could be electrons or holes). The Cbc-p 112 outside the area of the emitter 102 is limited by the width of the base contact 110 and the width of the emitter isolation spacer. The emitter isolation spacer is the dielectrics on the edge of the emitter 102 to isolate the emitter 102 from the base contact 110.

The Cbc-p 112 can be a significant portion of the overall Cbc. Accordingly, the present disclosure provides an HBT that eliminates the Cbc-p 112 by removing the substrate (e.g., substrate 108) and patterning the collector 106 so that it is aligned to the emitter 102.

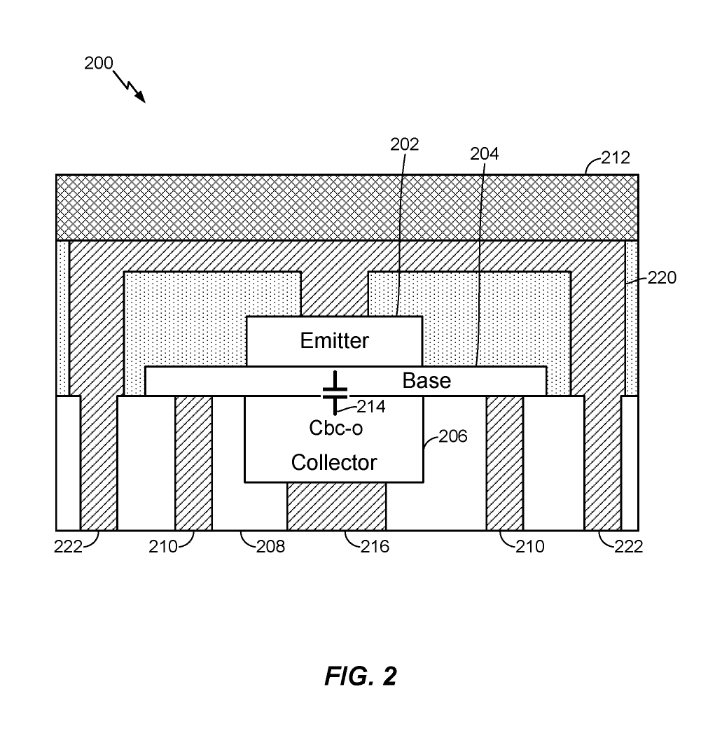

FIG. 2 is a simplified diagram of an exemplary HBT 200 according to at least one aspect of the disclosure. The HBT 200 includes an emitter 202, a base 204, a collector 206, a passivation layer 208, two base contacts 210, a collector contact 216, an emitter contact 220, two conductive connectors 222 coupled to the emitter contact 220, and a support structure 212. Like the HBT 100, the HBT 200 uses different semiconductor materials for the junction between the emitter 202 and the base 204 and the junction between the base 204 and the collector 206, thereby resulting in “heterojunctions.”

The HBT 200 may be permanently bonded to the support structure 212. The emitter contact 220 conductively couples the emitter 202 to the conductive connectors 222 in the passivation layer 208. The HBT 200 may be incorporated into a semiconductor device (not shown), and the base contacts 210, the conductive connectors 222, and the collector contact 216 may conductively couple the HBT 200 to the package balls (not shown) on the semiconductor device. As can be seen in FIG. 2, the Cbc-p portion of the overall Cbc of the HBT 200 has been eliminated. The Cbc of the HBT 200 is now only the Cbc-o 214.

As shown in FIG. 2, the collector 206 is smaller than the base 204, and is substantially the same width as the emitter 202. In the design of the HBT 200, the current flow through the HBT 200 is in series, and the thermal path is under the collector 206. Specifically, heat is generated inside the collector (e.g., collector 106 or collector 206). Conventionally, heat generated in the collector 106 is dissipated through the base 104, the emitter 102, the emitter contact 118, and then the bumps of the HBT 100 (not shown in FIG. 1). In contrast, as illustrated in FIG. 2, the heat generated by the collector 206 is dissipated through the collector contact 216 to the bumps (not shown in FIG. 2).

In greater detail, as shown in FIG. 1, the conventional thermal dissipation path (e.g., emitter contact 118) is on top of the emitter 102. This causes greater thermal resistance due to the base 104 and the emitter 102, in comparison to the direct contact of the thermal dissipation path (e.g., collector contact 216) to the collector 206 in the present disclosure. There are a number of benefits to this design, including that it enables vertical interconnection (referred to herein as “vertical access”) to the collector 206, reduces Cbc, enhances heat dissipation, and allows for a possible Faraday cage for electrical isolation.

More specifically, with reference to the vertical access to the collector 206, conventionally, the collector 106 is on top of the substrate 108 (an electrical insulator). To get current out of the collector 106, it will conduct laterally first (sub-collector), then to the collector contacts 116 on the side of the collector 106. In contrast, the design of the HBT 200, for example, allows current to travel vertically through the collector 206 and the collector contact 216.

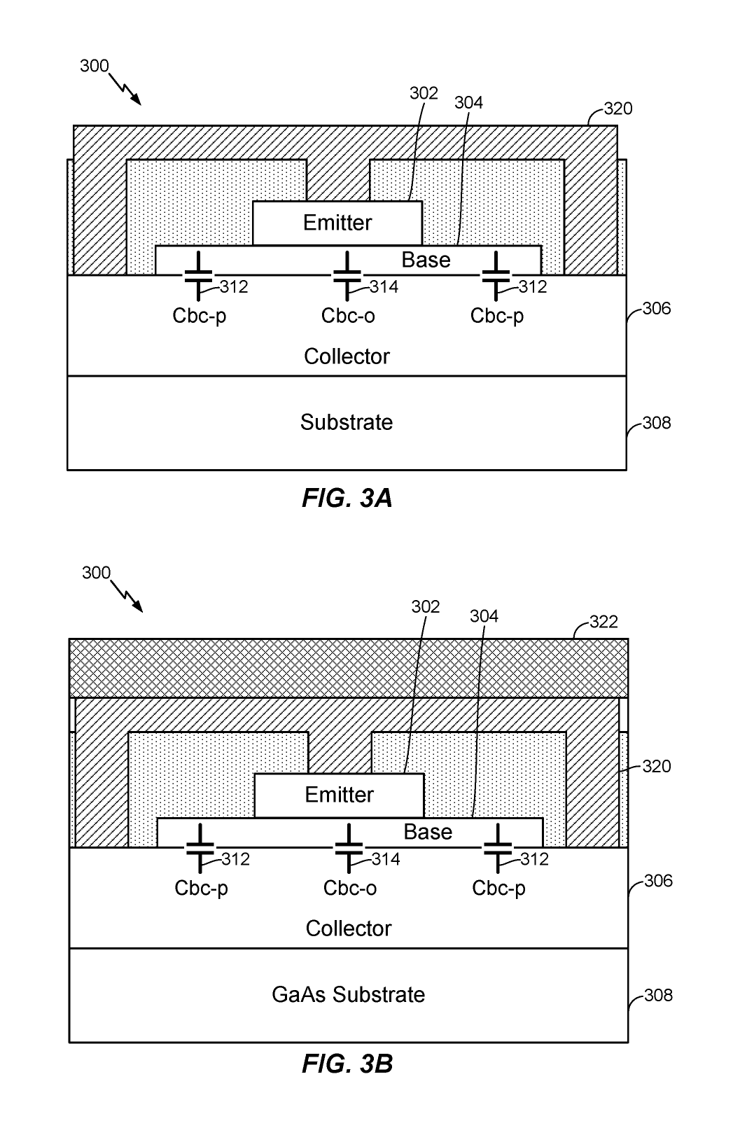

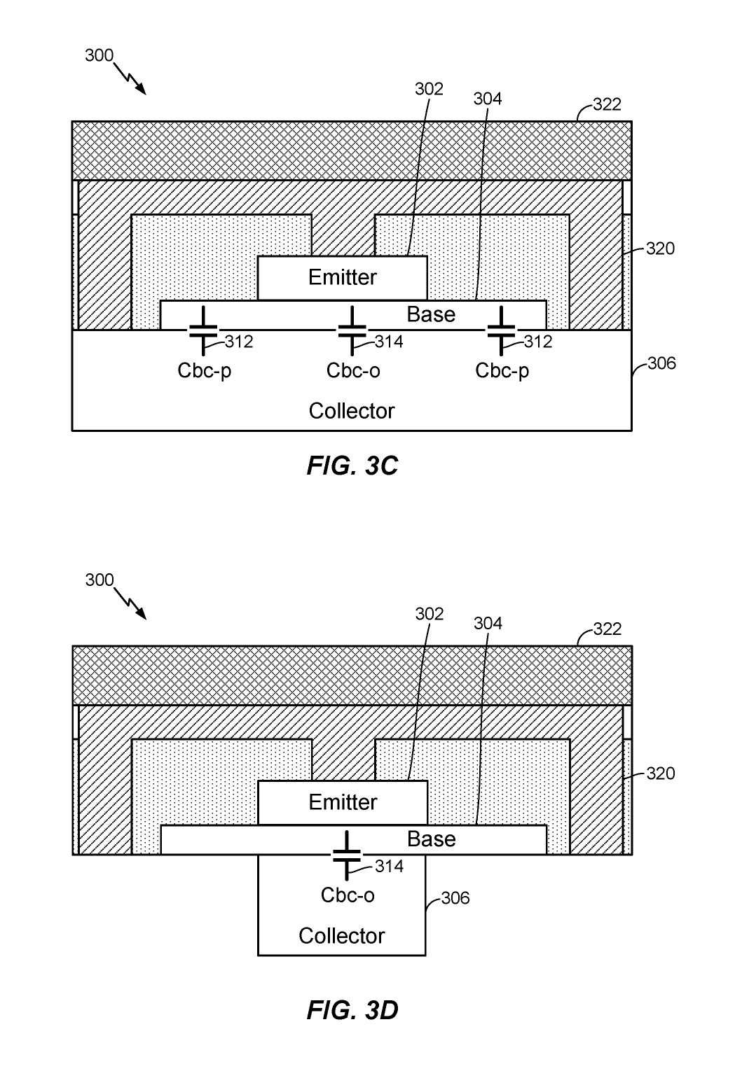

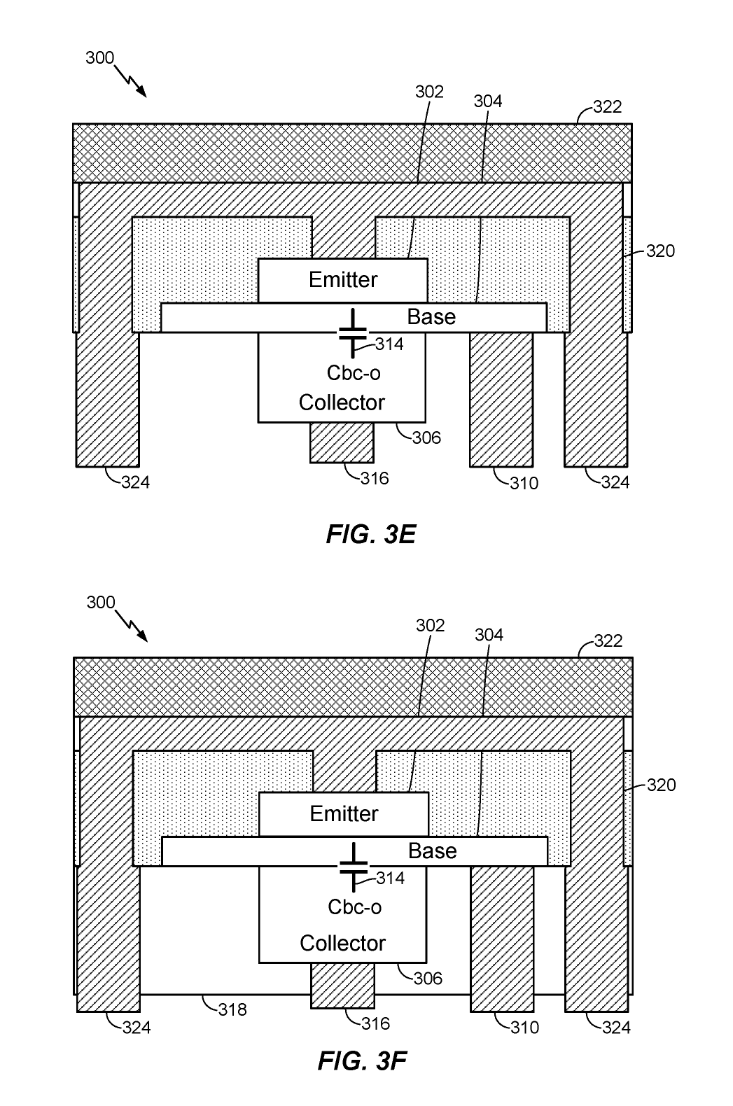

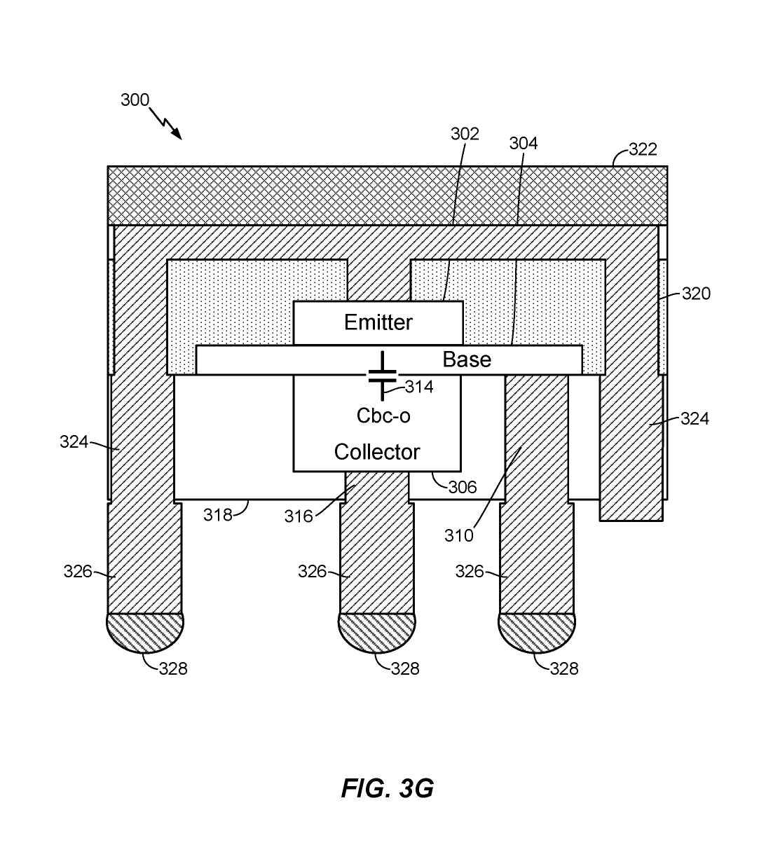

FIGS. 3A-3G illustrate a series of exemplary operations for fabricating an exemplary HBT, such as HBT 200, according to at least one aspect of the disclosure. In FIG. 3A, fabrication of an HBT according to aspects of the disclosure begins with an HBT structure 300 having an emitter 302 (such as emitter 102 in FIG. 1 or emitter 202 in FIG. 2), a base 304 (such as base 104 in FIG. 1 or base 204 in FIG. 2), a collector 306 (such as collector 106 in FIG. 1 or collector 206 in FIG. 2), and a substrate 308 (such as substrate 108 in FIG. 1).

As shown in FIG. 3A, the Cbc of the HBT structure 300 is divided into the Cbc-o 314, i.e., the Cbc of the junction between the base 304 and the collector 306 underneath the emitter 302, and the Cbc-p 312, i.e., the Cbc of the junction between the base 304 and the collector 306 outside of the area of the emitter 302. In the fabrication operation illustrated in FIG. 3A, an emitter contact 320, such as the emitter contact 220 in FIG. 2, is layered onto the HBT structure 300.

In the fabrication operation illustrated in FIG. 3B, the HBT structure 300 is permanently bonded to a support structure 322, such as support structure 212 in FIG. 2. The support structure 322 may be glass, silicon, or copper, for example. However, copper will have better thermal conductivity and grounding properties. Specifically, for conventional emitter PA designs, such as illustrated in FIG. 1, the emitter (e.g., emitter 102) is conductively connected to the ground. If copper is used as the support structure, it can provide higher electrical conductivity and a better electrical ground.

In the fabrication operation illustrated in FIG. 3C, the substrate 308 is removed from the HBT structure 300. The substrate 308 may be removed by grinding and using selective etch, which stops at the collector 306.

In the fabrication operation illustrated in FIG. 3D, the portion of the collector 306 outside of the area of the emitter 302 is removed. The collector 306 may be patterned using selective etch, which stops at the base 304.

In the fabrication operation illustrated in FIG. 3E, the metallization of the base 304 and the collector 306 is performed. Specifically, a base contact 310 (such as base contacts 210 in FIG. 2), conductive connectors 324 (such as conductive connectors 222 in FIG. 2), and a collector contact 316 (such as collector contact 216 in FIG. 2) are added to the HBT structure 300. The metallization may be performed using lithography, sputtering, and lift off. Note that in the example of FIG. 3E, there is only one base contact 310 coupled to the base 304. This single base contact 310 may be coupled to the base 304 on either side of the base 304 (i.e., either the right side or the left side of the base 304 from the perspective illustrated in FIG. 3E). Alternatively, there may be base contacts 310 coupled to the base 304 on both sides of the base 304, as in the example of FIG. 2. More specifically, there may be a single base contact 310 (as in FIG. 3E), two base contacts (e.g., 210 in FIG. 2), or more than two base contacts, depending on the design of the HBT structure 300. Alternatively, the base contact 310 could also be connected to the base 304 from the front side of the base 304, i.e., the side opposite the collector 306.

In the fabrication operation illustrated in FIG. 3F, a passivation layer 318 (such as passivation layer 208 in FIG. 2) is added to the HBT structure 300. The passivation layer 318 provides electrical isolation, and may be silicon dioxide (SiO2), silicon nitride (SiN), polyamide, etc. The passivation layer can also passivate the surface(s) to which it is applied. For example, SiN may be required to passivate the defects from the manufacturing process illustrated in FIGS. 3A-E.

After the fabrication operation illustrated in FIG. 3F, the HBT structure 300 is complete. If the HBT structure 300 is to be incorporated into a semiconductor device (not shown), then in the fabrication operation illustrated in FIG. 3G, the HBT structure 300 is mounted to the semiconductor device using conductive (e.g., copper) pillars 326 coupled to package balls 328. The conductive pillar 326 coupled to the collector contact 316 under the collector 306 will conduct heat from the collector 306 with the least thermal resistance. This is generally the thermal path with the least thermal resistance. More specifically, this pathway provides a direct metal connection to the heat source (i.e., the collector 306), and further, the support structure 322 (Si or Cu) has much higher thermal conductivity than GaAs to dispate heat from the top.

The contacts 110, 116, 118, 210, 216, 220, 222, 310, 316, 320, 324, and 326 are conductive pathways and may be one or more layers of aluminum (Al), copper (Cu), tin (Sn), nickel (Ni), gold (Au), silver (Ag), or other suitable electrically conductive material, as is known in the art. The package balls 328 may contain Cu, Sn, Ni, Au, Ag, lead (Pb), bismuth (Bi), or combinations thereof, with an optional flux solution, as is known in the art.

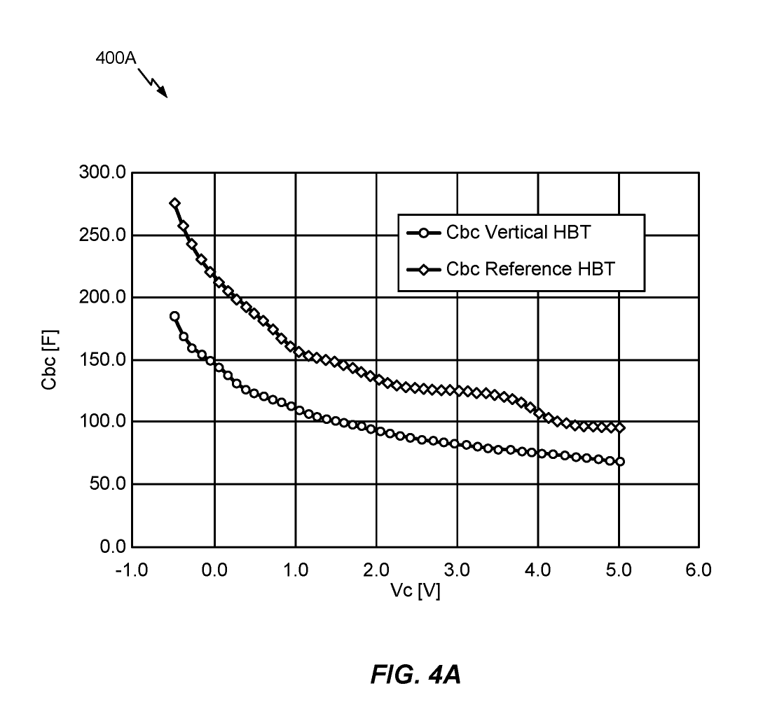

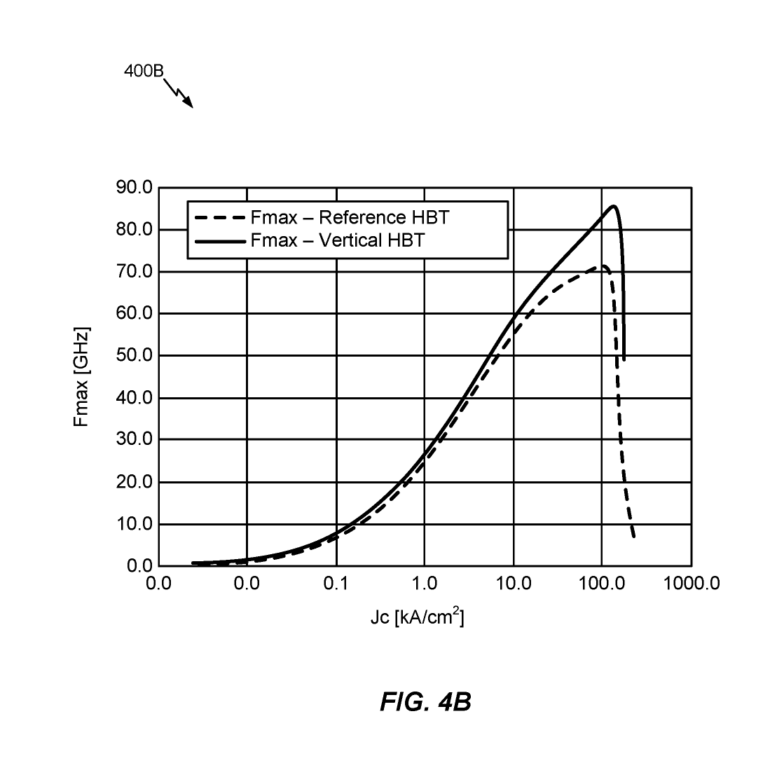

FIGS. 4A and 4B are two graphs illustrating the improved performance of the HBT of the present disclosure (e.g., HBT 200) over a conventional HBT (e.g., HBT 100). In FIG. 4A, graph 400A illustrates a comparison of Cbc in Farads (F) versus voltage (Vc) in volts (V). In FIG. 4A, the curve with the diamond points represents the performance of a conventional (or reference) HBT. The curve with the circle points represents the performance of an HBT according to the present disclosure (i.e., a vertical HBT). As shown in graph 400A, a vertical access HBT as disclosed herein (e.g., HBT 200) provides a Cbc reduction of approximately 30% compared to a conventional (reference) HBT.

In FIG. 4B, graph 400B illustrates a comparison of the maximum frequency (F.) in gigahertz (GHz) versus current density (Jc) in kiloampere per square centimeter (kA/cm²). In FIG. 4B, the dashed line represents the performance of a conventional (or reference) HBT. The solid line represents the performance of an HBT according to the present disclosure (i.e., a vertical HBT). As shown in FIG. 4B, the Fₘₐₓ of an HBT of the present disclosure (e.g., HBT 200) is improved over conventional HBTs (e.g., HBT 100) by approximately 20%. This increase of 20% in Fₘₐₓ is a 20% increase in the operating frequency for the device and is due to the relation between Fₘₐₓ and Cbc.

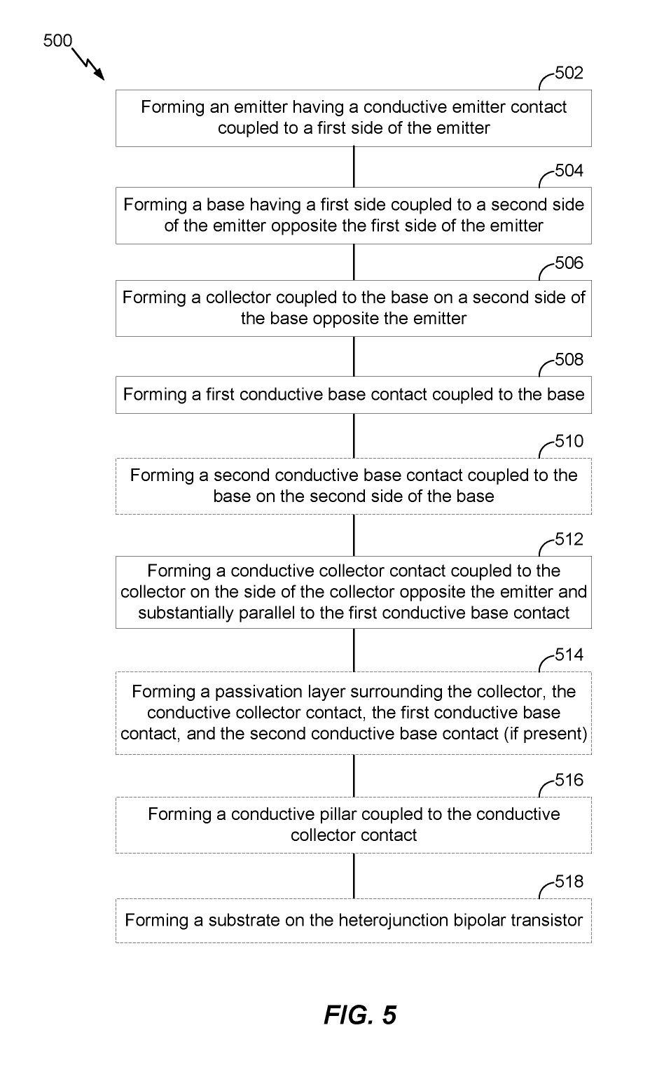

FIG. 5 illustrates an exemplary process 500 for manufacturing a heterojunction bipolar transistor according to at least one aspect of the disclosure. The process 500 may be performed by any manufacturing machinery capable of performing the operations illustrated in FIG. 5. In an aspect, the heterojunction bipolar transistor may be a component of a desktop computer, a laptop computer, a tablet computer, a server computer, a television, a cellular phone, a personal digital assistant, an audio amplifier, a radio transmitter, or any electrical device having transistors.

At 502, the process 500 includes forming an emitter, such as emitter 202 in FIG. 2, having a conductive emitter contact, such as emitter contact 220 in FIG. 2, coupled to a first side of the emitter.

At 504, the process 500 includes forming a base, such as base 204 in FIG. 2, having a first side coupled to a second side of the emitter opposite the first side of the emitter.

At 506, the process 500 includes forming a collector, such as collector 206 in FIG. 2, coupled to the base on a second side of the base opposite the emitter, as described above with reference to FIG. 3D. In an aspect, the area of the junction between the base and the collector may be less than or equal to an area of the junction between the base and the emitter. The area of the junction between the base and the collector being less than or equal to the area of the junction between the base and the emitter eliminates base-to-collector capacitance outside of the area of the junction between the base and the emitter. In an aspect, the junction between the base and the collector may be substantially the same width as the junction between the base and the emitter and may be substantially aligned with the emitter.

At 508, the process 500 includes forming a first conductive base contact, such as base contact 210 in FIG. 2, coupled to the base, as described above with reference to FIG. 3E. In an aspect, the conductive emitter contact may have a connection extending outside the base and providing a connection point on the same side of the base as the first conductive base contact. In an aspect, the first conductive base contact may be coupled to the base on the first side of the base or on the second side of the base.

At 510, the process 500 optionally includes forming a second conductive base contact, such as base contact 210 in FIG. 2, coupled to the base on the second side of the base, as described above with reference to FIG. 3E.

At 512, the process 500 includes forming a conductive collector contact, such as collector contact 216 in FIG. 2, coupled to the collector on the side of the collector opposite the emitter and substantially parallel to the first conductive base contact, as described above with reference to FIG. 3E. In an aspect, the conductive collector contact may be between the first conductive base contact and the second conductive base contact.

At 514, the process 500 optionally includes forming a passivation layer, such as passivation layer 318 in FIG. 3F, surrounding the collector, the conductive collector contact, the first conductive base contact, and the second conductive base contact (if present), as described above with reference to FIG. 3F.

At 516, the process 500 optionally includes forming a conductive pillar, such as conductive pillars 326 in FIG. 3G, coupled to the conductive collector contact, as described above with reference to FIG. 3G.

At 518, the process 500 optionally includes forming a substrate, such as support structure 322 in FIG. 3B, on the heterojunction bipolar transistor, as described above with reference to FIG. 3B. In an aspect, the conductive emitter contact may be coupled to the substrate. The substrate may be silicon, copper, sapphire, stainless steel, etc.

Note that as used herein, the terms “substantially” and “approximately” are not relative terms of degree, but rather, reflect the reality that, due to tolerances in manufacturing processes, two components may not be exactly the same size or have an exact orientation with respect to each other, or that a given component may not be an exact size. Rather, the terms “substantially” and “approximately” mean that the size, orientation, etc. of the component(s) need only be within some tolerance threshold of the described size, orientation, etc. Thus, for example, when one component is described as being “substantially” above or below another component, it means that the components are aligned vertically within some tolerance threshold. Similarly, as another example, when one component is described as being “approximately” a given size, it means that the component is within a given tolerance threshold of the given size. The tolerance threshold may be determined by the capabilities of the manufacturing process, the requirements of the device and/or components being manufactured, and the like.

It will be appreciated that even if the terms “substantially” or “approximately” are not used to describe a size, orientation, etc. of component(s), it does not mean that the size, orientation, etc. of the component(s) must be exactly the described size, orientation, etc. Rather, the described size, orientation, etc. need only be within some tolerance threshold of the described size, orientation, etc.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A heterojunction bipolar transistor comprising:
an emitter having a conductive emitter contact coupled to a first side of the emitter;
a first side of a base coupled to a second side of the emitter opposite the first side of the emitter;
a collector coupled to the base on a second side of the base opposite the emitter, wherein an area of a junction between the base and the collector is less than or equal to an area of a junction between the base and the emitter;
a first conductive base contact coupled to the base; and
a conductive collector contact coupled to the collector on the side of the collector opposite the emitter and substantially parallel to the first conductive base contact.

2. The heterojunction bipolar transistor of claim 1, wherein the area of the junction between the base and the collector being less than or equal to the area of the junction between the base and the emitter eliminates base-to-collector capacitance outside of the area of the junction between the base and the emitter.

3. The heterojunction bipolar transistor of claim 1, wherein the first conductive base contact is coupled to the base on the second side of the base.

4. The heterojunction bipolar transistor of claim 3, further comprising:
a second conductive base contact coupled to the base on the second side of the base, wherein the conductive collector contact is between the first conductive base contact and the second conductive base contact.

5. The heterojunction bipolar transistor of claim 3, wherein the conductive emitter contact has a connection extending outside the base and providing a connection point on a same side of the base as the first conductive base contact.

6. The heterojunction bipolar transistor of claim 3, further comprising:
a passivation layer surrounding the collector, the conductive collector contact, and the first conductive base contact.

7. The heterojunction bipolar transistor of claim 1, wherein the junction between the base and the collector is substantially a same width as the junction between the base and the emitter and is substantially aligned with the emitter.

8. The heterojunction bipolar transistor of claim 1, further comprising:
a conductive pillar coupled to the conductive collector contact.

9. The heterojunction bipolar transistor of claim 1, further comprising a substrate, wherein the conductive emitter contact is coupled to the substrate.

10. The heterojunction bipolar transistor of claim 9, wherein the substrate comprises silicon, copper, sapphire, or stainless steel.

11. The heterojunction bipolar transistor of claim 1, wherein the heterojunction bipolar transistor is a component of a desktop computer, a laptop computer, a tablet computer, a server computer, a television, a cellular phone, a personal digital assistant, an audio amplifier, or a radio transmitter.

12. The heterojunction bipolar transistor of claim 1, wherein the first conductive base contact is coupled to the base on the first side of the base.

13. A method of manufacturing a heterojunction bipolar transistor comprising:
forming an emitter having a conductive emitter contact coupled to a first side of the emitter;
forming a base having a first side coupled to a second side of the emitter opposite the first side of the emitter;
forming a collector coupled to the base on a second side of the base opposite the emitter, wherein an area of a junction between the base and the collector is less than or equal to an area of a junction between the base and the emitter;
forming a first conductive base contact coupled to the base; and
forming a conductive collector contact coupled to the collector on the side of the collector opposite the emitter and substantially parallel to the first conductive base contact.

14. The method of claim 13, wherein the area of the junction between the base and the collector being less than or equal to the area of the junction between the base and the emitter eliminates base-to-collector capacitance outside of the area of the junction between the base and the emitter.

15. The method of claim 13, wherein the first conductive base contact is coupled to the base on the second side of the base.

16. The method of claim 15, further comprising:
forming a second conductive base contact coupled to the base on the second side of the base, wherein the conductive collector contact is between the first conductive base contact and the second conductive base contact.

17. The method of claim 15, wherein the conductive emitter contact has a connection extending outside the base and providing a connection point on a same side of the base as the first conductive base contact.

18. The method of claim 15, further comprising:
forming a passivation layer surrounding the collector, the conductive collector contact, and the first conductive base contact.

19. The method of claim 13, wherein the junction between the base and the collector is substantially a same width as the junction between the base and the emitter and is substantially aligned with the emitter.

20. The method of claim 13, further comprising:
forming a conductive pillar coupled to the conductive collector contact.

21. The method of claim 13, further comprising:
forming a substrate on the heterojunction bipolar transistor, wherein the conductive emitter contact is coupled to the substrate.

22. The method of claim 21, wherein the substrate comprises silicon, copper, sapphire, or stainless steel.

23. The method of claim 13, wherein the heterojunction bipolar transistor is a component of a desktop computer, a laptop computer, a tablet computer, a server computer, a television, a cellular phone, a personal digital assistant, an audio amplifier, or a radio transmitter.

24. The method of claim 13, wherein the first conductive base contact is coupled to the base on the first side of the base.

25. A heterojunction bipolar transistor comprising:
means for emitting having a conductive emitter contact coupled to a first side of the means for emitting;
a first side of a means for providing a base coupled to a second side of the means for emitting opposite the first side of the means for emitting;
means for collecting coupled to the means for providing the base on a second side of the means for providing the base opposite the means for emitting, wherein an area of a junction between the means for providing the base and the means for collecting is less than or equal to an area of a junction between the means for providing the base and the means for emitting;
a first conductive base contact coupled to the means for providing the base; and
a conductive collector contact coupled to the means for collecting on the side of the means for collecting opposite the means for emitting and substantially parallel to the first conductive base contact.

26. The heterojunction bipolar transistor of claim 25, wherein the area of the junction between the means for providing the base and the means for collecting being less than or equal to the area of the junction between the means for providing the base and the means for emitting eliminates base-to-collector capacitance outside of the area of the junction between the means for providing the base and the means for emitting.

27. The heterojunction bipolar transistor of claim 25, wherein the junction between the means for providing the base and the means for collecting is substantially a same width as the junction between the means for providing the base and the means for emitting and is substantially aligned with the means for emitting.

28. The heterojunction bipolar transistor of claim 25, wherein the first conductive base contact is coupled to the means for providing the base on the second side of the means for providing the base.

29. The heterojunction bipolar transistor of claim 28, wherein the conductive emitter contact has a connection extending outside the means for providing the base and providing a connection point on a same side of the means for providing the base as the first conductive base contact.

30. The heterojunction bipolar transistor of claim 28, further comprising:
means for passivation surrounding the means for collecting, the conductive collector contact, and the first conductive base contact.

31. The heterojunction bipolar transistor of claim 25, wherein the heterojunction bipolar transistor is a component of a desktop computer, a laptop computer, a tablet computer, a server computer, a television, a cellular phone, a personal digital assistant, an audio amplifier, or a radio transmitter.

32. The heterojunction bipolar transistor of claim 25, wherein the first conductive base contact is coupled to the means for providing the base on the first side of the means for providing the base.

33. The heterojunction bipolar transistor of claim 25, further comprising:
means for electrically insulating formed on the heterojunction bipolar transistor, wherein the conductive emitter contact is coupled to the means for electrically insulating.
